(19) United States
(12) Patent Application Publication
(10) Pub. No.: US 2011/0001732 A1
(43) Pub. Date: Jan. 6, 2011

(54) SHIFT REGISTER CIRCUIT, DISPLAY DEVICE, AND METHOD FOR DRIVING SHIFT REGISTER CIRCUIT

(76) Inventors: Hideki Morii, Osaka (JP); Akihisa Iwamoto, Osaka (JP); Takayuki Mizunaga, Osaka (JP); Yuuki Ohta, Osaka (JP); Masahiro Hirokane, Osaka (JP); Shinya Tanaka, Osaka (JP); Hajime Imai, Osaka (JP); Tetsuo Kikuchi, Osaka (JP)

Correspondence Address: HARNESS, DICKEY & PIERCE, P.L.C., P.O. BOX 8910, RESTON, VA, 20195, US

(21) Appl. No.: 12/735,771

(22) PCT Filed: Oct. 22, 2008
(86) PCT No.: PCT/JP2008/069145

§ 371 Date: Sep. 7, 2010

(30) Foreign Application Priority Data
Feb. 19, 2008 (JP) 2008-037627

(51) Int. Cl. G09G 5/00; G11C 19/36

(52) U.S. Cl. 345/204; 377/79

(57) ABSTRACT

In at least one embodiment, each of stages connected in cascade includes a first circuit which causes a predetermined section in a corresponding one of the stages to be connected to a low-potential power source, the first circuit being constituted by TFTs, a first type of clock signal being used as a signal which is transferred to an output terminal of each of the stages so as to be outputted as an output signal, a second type of clock signal being used as a signal which drives the first circuit. With the arrangement, it is possible to realize a shift register circuit that is capable of further suppressing a shift phenomenon of a threshold voltage in each of the TFTs.

### TECHNICAL FIELD

The present invention relates to a shift register circuit that is monolithically integrated with a display panel.

### BACKGROUND ART

In recent years, the fabrication of a monolithic gate driver has been developed for the purpose of cost reduction. The monolithic gate driver is such a gate driver that is formed from amorphous silicon on a liquid crystal panel. The term “monolithic gate driver” is also associated with the terms such as “gate driver-free”, “built-in gate driver in panel”, and “gate in panel”.

FIG. 6 shows an exemplary configuration of a shift register circuit which constitutes a gate driver which is monolithically integrated with a display panel.

In the shift register circuit, stages SR ( . . . , SRn−1, SRn, SRn+1, . . . ) each includes a set input terminal Gn−1, an output terminal Gn, a reset input terminal Gn+1, a Low power source input terminal VSS, and a clock signal input terminal CK. To the set input terminal Gn−1 of each stage SR, an output signal OUT ( . . . , OUTn−1, OUTn, OUTn+1, . . . ) of its preceding stage is inputted. The output terminal Gn of each stage SR outputs an output signal OUT to a corresponding scan signal line. To the reset input terminal Gn+1 of each stage SR, an output signal OUT of its subsequent stage is inputted. To the Low power source input terminal VSS of each stage SR, a Low power source voltage VSS which is a power source voltage of a low level electric potential for the stage SR is inputted. In the shift register circuit, (i) a stage in which a clock signal CK1 is inputted to its clock signal input terminal CK and (ii) a stage in which a clock signal CK2 is inputted to its clock signal input terminal CK are alternated. The clock signals CK1 and CK2 do not overlap with each other in an active clock pulse period, as shown in FIG. 8. A high level voltage of each of the clock signals CK1 and CK2 is VGH, and a low level voltage of each of the clock signals CK1 and CK2 is VGL. The Low power source voltage. VSS is equal to the low level voltage VGL of each of the clock signals CK1 and CK2.

FIG. 7 shows an exemplary configuration of each of the stages SR of the shift register circuit shown in FIG. 6. This configuration is the one disclosed in Non Patent Literature 1.

Each of the stages SR includes four transistors Tr1, Tr2, Tr3 and Tr4, and a capacitor CAP1. These transistors are all n-channel type TFTs.

As to the transistor Tr1, a gate and a drain are connected to a set input terminal Gn−1, and a source is connected to a gate of the transistor Tr4. As to the transistor Tr4, a drain is connected to a clock signal input terminal CK, and a source is connected to an output terminal Gn. That is, the transistor Tr4 serves as a transfer gate to perform passage and interruption of a clock signal to be supplied to the clock input terminal CK. The capacitor CAP1 is provided between the gate and the source of the transistor Tr4. A node that is conducted to the gate of the transistor Tr4 to have the same potential as it is referred to as a netA.

As to the transistor Tr2, a gate is connected to a reset input terminal Gn+1, a drain is connected to the node netA, and a source is connected to a Low power source input terminal VSS. As to the transistor Tr3, a gate is connected to the reset input terminal Gn+1, a drain is connected to the output terminal Gn, and a source is connected to the Low power source input terminal VSS.

Next, with reference to FIG. 8, the following will describe operations of each stage SR configured as shown in FIG. 7.

Until a shift pulse is supplied to the set input terminal Gn−1, the transistors Tr3 and Tr4 are in a high impedance state. This causes the output terminal Gn to be held Low.

When to the set input terminal Gn−1 of each stage SR, a gate pulse (i.e., shift pulse) of an output signal OUT (OUTn−1 in FIG. 8) of its preceding stage is supplied, a period in which the output terminal Gn generates an output pulse starts. This causes the transistor Tr1 to be turned ON, which charges the capacitor CAP1. Charging of the capacitor CAP1 increases a potential of the node netA and causes the transistor Tr4 to be turned ON. This causes the clock signal supplied through the clock signal input terminal CK to appear at the source of the transistor Tr4. At the instant when the clock pulse is supplied to the clock signal input terminal CK, the potential of the node netA is pumped up due to the bootstrap effect of the capacitor CAP1, and the incoming clock pulse is transferred to the output terminal Gn of the stage SR and outputted from the output terminal Gn as a gate pulse (pulse of an output signal OUTn, here).

When the supply of the gate pulse to the set input terminal Gn−1 is completed, the transistor Tr1 is turned OFF. Then, in order to release charge retention caused by floating of the node netA and the output terminal Gn of the stage SR, the transistors Tr2 and Tr3 are turned ON by a reset pulse supplied to the reset input terminal Gn+1, and the node netA and the output terminal Gn are connected to the Low power source voltage VSS. This causes the transistor Tr4 to be turned OFF. When the supply of the reset pulse is completed, the period in which the output terminal Gn generates the output pulse ends, and the period in which the output terminal Gn is held Low starts again.

In this manner, gate pulses are sequentially outputted to respective gate lines.

In the shift register circuit, the transistors Tr3 and Tr4 are in a high impedance state during the period in which the output terminal Gn is held Low. This causes the output terminal Gn to be in a floating state. In order to prevent a state where the output terminal Gn cannot be held Low due to noise propagated, for example, by cross-coupling between a gate bus line and a source bus line, a so-called sink-down transistor is provided which causes the output terminal Gn to be connected to the Low power source voltage VSS of a low level during the period in which the output terminal Gn is held Low. Moreover, the transistor Tr2 is also in a high impedance state during the period in which the output terminal Gn is held Low. This causes the node netA to be in a floating state. Therefore, in order to prevent leakage of the transistor Tr4, a sink-down transistor is provided which causes the node netA to be connected to the Low power source voltage VSS during the period in which the output terminal Gn is held Low.

However, the provision of the sink-down transistors which cause the output terminal Gn and the node netA to be connected to the low level source causes a DC bias to be always applied to gates of these transistors, thereby causing shift phenomenon of a threshold voltage. This is also described in Non Patent Literature 1. This shift phenomenon of a threshold value is remarkable especially under high temperature. In the case of n-channel type TFT, the threshold voltage is shifted upward. In a case where the shift phenomenon of a threshold voltage occurs in the transistor which causes the output terminal Gn to be connected to the low level source, it becomes gradually difficult for the transistor to be turned ON, thereby making it difficult to connect the output terminal Gn to the low level source. Further, in a case where the shift phenomenon of a threshold voltage occurs in the transistor which causes the node netA to be connected to the low level source, it becomes gradually difficult for the transistor to be turned ON, thereby making it difficult to connect the note netA to the low level source. As such, when an electric potential of the node netA is increased due to its own unstableness, leakage of the transistors etc., leakage of an output transistor (the transistor Tr4 in FIG. 7) occurs, thereby making it difficult to keep the output terminal Gn at the low level.

The shift phenomenon of a threshold voltage causes a TFT to lose its switching function after long-term operation since a DC bias is always applied to a gate of the TFT. This ultimately leads the shift register circuit to such malfunction as to prevent fulfilling the original function. As a result, it becomes impossible to prevent a gate bus line from being affected by electric potential fluctuation of a source bus line etc., thereby leading to occurrence of a crosstalk. This makes it impossible to stably carry out display.

In view of the circumstances, Non Patent Literature 1 proposes a shift register circuit that is configured such that a period in which an ON voltage is applied to a gate of such a sink-down TFT is shortened.

FIGS. 9 and 10 show a configuration of a shift register circuit that is similar to this shift register circuit.

The shift register circuit shown in FIG. 9 is configured such that the clock signal input terminal CK of each stage SR in the shift register circuit of FIG. 6 is replaced with clock signal input terminals CKa and CKb. To the clock signal input terminal CKa, one of the clock signals CK1 and CK2 is inputted, and to the clock signal input terminal CKb, the other one of the clock signals CK1 and CK2 is inputted. Specifically, a first stage and a second stage are alternately provided, the first stage being such that the clock signal CK1 is inputted to the clock signal input terminal CKa and the clock signal CK2 is inputted to the clock signal input terminal CKb, and the second stage being such that the clock signal CK2 is inputted to the clock signal input terminal CKa, and the clock signal CK1 is inputted to the clock signal input terminal CKb. The clock signals CK1 and CK2 do not overlap with each other in an active clock pulse period, as shown in FIG. 11. A high level voltage of each of the clock signals CK1 and CK2 is VGH, and a low level voltage of each of the clock signals CK1 and CK2 is VGL. The low power source voltage VSS is equal to the low level voltage VGL of each of the clock signals CK1 and CK2.

FIG. 10 shows an exemplary configuration of each of the stages SR of the shift register circuit of FIG. 9.

The stage SR shown in FIG. 10 includes sink-down transistors Tr5 through Tr7, each of which is an n-channel type TFT, and an AND gate 101 of two inputs in addition to the configuration of FIG. 7.

As to the transistor Tr5, a gate is connected to a clock signal input terminal CKa, a drain is connected to a node netA, and a source is connected to an output terminal Gn. As to the transistor Tr6, a gate is connected to an output of the AND gate 101, a drain is connected to the output terminal Gn, and a source is connected to a Low power source input terminal VSS. As to the transistor Tr7, a gate is connected to a clock signal input terminal CKb, a drain is connected to an output terminal Gn, and a source is connected to the Low power source input terminal VSS. As to the AND gate 101, one input terminal is connected to the clock signal input terminal CKa, and the other low-active input terminal is connected to the output terminal Gn.

Next, with reference to FIG. 11, the following will describe operations of each stage SR configured as shown in FIG. 10.

Although an operation of outputting an output signal OUT to the output terminal Gn is similar to that of FIG. 8, each of the transistors Tr5, Tr6, and Tr7 and the AND gate 101 executes an additional operation during a period in which the output terminal Gn is held Low.

The transistor Tr5 is turned ON every time it receives a clock pulse of the clock signal CK1 or the clock signal CK2 (the clock signal CK1 in FIG. 11) inputted to the clock signal input terminal CKa, so that the node netA and the output terminal Gn are short-circuited. As long as the output terminal Gn is held Low, the AND gate 101 outputs a signal of high level every time it receives the clock pulse of the clock signal (the clock signal CK1 in FIG. 11) inputted to the clock signal input terminal CKa, so that the transistor Tr6 is turned ON. The transistor Tr7 is turned ON every time it receives a clock pulse of the clock signal CK1 or the clock signal CK2 (the clock signal CK2 in FIG. 11) inputted to the clock signal input terminal CKb, so that the output terminal Gn is connected to the Low power source voltage VSS.

A period in which the transistor Tr6 is being turned ON and a period in which the transistor Tr7 is being turned ON are alternated, and the voltage of the output terminal Gn sinks down during these periods. The voltage of the node netA sinks down while the transistor Tr5 is being turned ON since the transistor Tr6 is also being turned ON while the transistor Tr5 is being turned ON.

In the operation shown in FIG. 11, a DC bias term set for each gate of the transistors Tr6 and Tr7 is cut down to a rate of approximately 50% which is equivalent to the ON duty-cycle of each clock signal, regardless of the fact that the period in which the voltage of the output terminal Gn sinks down is large, i.e., a sum of a clock pulse period of the clock signal CK1 and a clock pulse period of the clock signal CK2. The same is true for a DC bias term of the transistor Tr5.

In this manner, in the shift register circuit configured as shown in FIGS. 9 through 11, a period in which a DC bias is applied to a sink-down TFT is shortened so that a shift phenomenon of a threshold voltage is suppressed.

Non Patent Literature 1
Seung-Hwan Moon et al., “Integrated a-Si:H TFT Gate Driver Circuits on Large Area TFT-LCDs”, SID 2007 46.1, pp 1478-1481

### SUMMARY OF INVENTION

Such a conventional shift register circuit shown in FIGS. 9 through 11 in which the DC bias term for a sink-down TFT is cut down to a rate of approximately 50% is considered to be resistant to aging due to long-term operation under high temperature of 50° C. which is normally the maximum operational temperature for a notebook computer or the like. However, a TFT liquid crystal module is not limited to an OA (Office Automation) application such as a notebook computer or a monitor, but has been increasingly used in a broader range of applications such as an FA (Factory Automation) application, an IA (Industry Application), and a vehicle application. In view of the circumstances, there is a demand for a technique which allows a TFT liquid crystal module to operate not only under 50° C., but also under higher temperature such as 85° C. (Industry Application) or 95° C. (vehicle application).

In other words, there is a demand for an a-Si gate monolithic shift register circuit that is more reliable than the shift register circuit configured as shown in FIGS. 9 through 11.

FIG. 12 shows a relationship between (i) a shift amount ΔVth of a threshold voltage and (ii) a DC bias term set for a gate in each of two types of TFTs (type 1 and type 2). The type 1 and the type 2 each have a channel length L of 4 μm and a channel width of 100 μm, but are different in structure. Their source voltages VS are set to 0V, their drain voltages Vd are set to 0.1V, and temperature is set to 85° C. Both of the type 1 and the type 2 show similar shift amounts ΔVth which at their gate voltages Vg of DC20V drastically increase as compared to at those of DC10V. As is clear from this, a shift amount ΔVth of a threshold voltage of a TFT largely depends on a DC bias applied to a gate.

The present invention was attained in view of the above problems, and an object of the present invention is to realize (i) a shift register circuit that is capable of suppressing a shift phenomenon of a threshold voltage of a TFT, (ii) a display device including the shift register circuit, and (iii) a method for driving the shift register circuit.

In order to attain the above object, a shift register circuit of the present invention is a shift register circuit to which at least one first type of clock signal and at least one second type of clock signal are supplied, the shift register circuit including stages which are connected in cascade, the stages each including a first circuit which causes a predetermined section in a corresponding one of the stages to be connected to a low-potential power source, the first circuit being constituted by a TFT, the at least one first type of clock signal being used as a signal which is supplied to an output terminal of each of the stages so as to be outputted as an output signal, the at least one second type of clock signal being used as a signal which drives the first circuit.

According to the invention, the at least one first type of clock signal is used as a signal which is supplied to an output terminal of each of the stages so as to be outputted as an output signal, and the at least one second type of clock signal is used as a signal which drives the first circuit. With the arrangement, it is possible to set a voltage level and a duty-cycle of the at least one second type of clock signal separately from the at least one first type of clock signal. This allows a DC bias applied to a gate of the TFT of the first circuit to be set in accordance with the voltage level and the duty-cycle of the at least one second type of clock signal. It is therefore possible to reduce the DC bias applied to the TFT in a case where the first circuit connects the predetermined section to a low-potential power source (i.e., sinks down the voltage of the predetermined section). This allows a shift amount of a threshold voltage to be kept very small.

The arrangement thus can produce an effect that it is possible to realize a shift register circuit that is capable of further suppressing a shift phenomenon of a threshold voltage of a TFT.

In order to attain the above object, a shift register circuit of the present invention is arranged such that the TFT is an n-channel type transistor, and a high level voltage of the at least one second type of clock signal is lower than that of the at least one first type of clock signal.

According to the invention, it is possible to produce an effect that even if the at least one first type of clock signal and the at least one second type of clock signal are the same in duty-cycle, a DC bias applied to the TFT can be set in accordance with the voltage level of the at least one second type of clock signal, i.e., can be made smaller, as compared to a case where the at least one first type of clock signal is used.

In order to attain the above object, a shift register circuit of the present invention is arranged such that the TFT is an n-channel type transistor, and a high level voltage of the at least one second type of clock signal is higher than that of the at least one first type of clock signal.

According to the invention, it is possible to produce an effect that in a case where a threshold voltage of the TFT is large, a value of a duty-cycle is set to be an appropriate one (e.g., set to be small) while the voltage level of the at least one second type of clock signal is set to be higher than that of the at least one first type of clock signal, thereby allowing a DC bias applied to the TFT to be smaller as compared to the case where the at least one first type of clock signal is used.

In order to attain the above object, a shift register circuit of the present invention is arranged such that the TFT is an n-channel type transistor, and an active clock pulse duty-cycle of the at least one second type of clock signal is smaller than that of the at least one first type of clock signal.

According to the invention, it is possible to produce an effect that even if the at least one first type of clock signal and the at least one second type of clock signal are the same in high level voltage, a DC bias applied to the TFT can be set in accordance with the duty-cycle of the at least one second type of clock signal, i.e., can be made smaller, as compared to a case where the at least one first type of clock signal is used.

In order to attain the above object, a shift register circuit of the present invention is arranged such that the TFT is an n-channel type transistor, and an active clock pulse duty-cycle of the at least one second type of clock signal is larger than that of the at least one first type of clock signal.

According to the invention, it is possible to produce an effect that in a case where a threshold voltage of the TFT is not large, a voltage level is set to be an appropriate one (e.g., set to be small) while the duty-cycle of the at least one second type of clock signal is set to be larger than that of the at least one first type of clock signal, thereby allowing a DC bias applied to the TFT to be smaller as compared to the case where the at least one first type of clock signal is used.

In order to attain the above object, a shift register circuit of the present invention is arranged such that the predetermined section is a pathway through which the output signal is transmitted.

According to the invention, it is possible to produce an effect that the pathway through which the output signal is transferred can stably sink down since the shift phenomenon of a threshold voltage can be suppressed.

In order to attain the above object, a shift register circuit of the present invention is arranged such the shift register circuit is made of amorphous silicon.

According to the invention, it is possible to produce an effect that a floating section specific to the shift register circuit which is made of amorphous silicon and which has only n-channel type TFTs can stably sink down since the shift phenomenon of a threshold voltage can be suppressed.

In order to attain the above object, a shift register circuit of the present invention is arranged such the shift register circuit is made of polycrystalline silicon.

According to the invention, it is possible to curb the threshold voltage shift of a sink-down transistor, even if it sinks potential of a floating spot which is liable to emerge in a shift register stage circuit with transistors only of n-type channel polarity and hence with its range of supply voltage set to be biased strongly toward one polarity side. This yields the effect of significantly improving circuit characteristics.

In order to attain the above object, a shift register circuit of the present invention is arranged such the shift register circuit is made of CG silicon.

According to the invention, it is possible to curb the threshold voltage shift of a sink-down transistor, even if it sinks potential of a floating spot which is liable to emerge in a shift register stage circuit with transistors only of n-type channel polarity and hence with its range of supply voltage set to be biased strongly toward one polarity side. This yields the effect of significantly improving circuit characteristics.

In order to attain the above object, a shift register circuit of the present invention is arranged such the shift register circuit is made of microcrystalline silicon.

According to the invention, it is possible to curb the threshold voltage shift of a sink-down transistor, even if it sinks potential of a floating spot which is liable to emerge in a shift register stage circuit with transistors only of n-type channel polarity and hence with its range of supply voltage set to be biased strongly toward one polarity side. This yields the effect of significantly improving circuit characteristics.

In order to attain the above object, a display device of the present invention is a display device including the shift register circuit which is used to drive display.

According to the invention, it is possible to produce an effect that display can be carried out well due to stable operations of the shift register circuit.

In order to attain the above object, a display device of the present invention is arranged such that the shift register circuit is used as a scan signal line driving circuit.

According to the invention, it is possible to produce an effect that the scan signal line can stably sink down so that display can be carried out well.

In order to attain the above object, a display device of the present invention is arranged such the shift register circuit is formed on a display panel so as to be monolithically integrated with a display region.

According to the invention, it is possible to produce an effect that the display device can carry out display well due to stable operation of the shift register circuit, the display device being advantageous in simplification of configuration since the shift register circuit is formed on the display panel so as to be monolithically integrated with the display region.

In order to attain the above object, a method for driving a shift register circuit according to the present invention is a method for driving a shift register circuit which includes stages connected in cascade, the stages each including a first circuit which causes a predetermined section in a corresponding one of the stages to be connected to a low-potential power source, the first circuit being constituted by a TFT, said method includes the step of: supplying at least one first type of clock signal and at least one second type of clock signal to the shift register circuit, said at least one first type of clock signal being used as a signal which is supplied to an output terminal of each of the stages so as to be outputted as an output signal, said at least one second type of clock signal being used as a signal which drives the first circuit.

According to the invention, the at least one first type of clock signal is used as a signal which is supplied to an output terminal of each of the stages so as to be outputted as an output signal, and the at least one second type of clock signal is used as a signal which drives the first circuit. With the arrangement, it is possible to set a voltage level and a duty-cycle of the at least one second type of clock signal separately from the at least one first type of clock signal. This allows a DC bias applied to a gate of the TFT of the first circuit to be set in accordance with the voltage level and the duty-cycle of the at least one second type of clock signal. It is therefore possible to reduce the DC bias applied to the TFT in a case where the first circuit connects the predetermined section to a low-potential power source (i.e., sinks down the voltage of the predetermined section). This allows a shift amount of a threshold voltage to be kept very small.

The arrangement thus can produce an effect that it is possible to realize a shift register circuit that is capable of further suppressing a shift phenomenon of a threshold voltage of a TFT.

In order to attain the above object, a method of the present invention is such that the TFT is an n-channel type transistor, and a high level voltage of the at least one second type of clock signal is lower than that of the at least one first type of clock signal.

According to the invention, it is possible to produce an effect that even if the at least one first type of clock signal and the at least one second type of clock signal are the same in duty-cycle, a DC bias applied to the TFT can be set in accordance with the voltage level of the at least one second type of clock signal, i.e., can be made smaller, as compared to a case where the at least one first type of clock signal is used.

In order to attain the above object, a method of the present invention is such that the TFT is an n-channel type transistor, and a high level voltage of the at least one second type of clock signal is higher than that of the at least one first type of clock signal.

According to the invention, it is possible to produce an effect that in a case where a threshold voltage of the TFT is large, a value of a duty-cycle is set to be an appropriate one (e.g., set to be small) while the voltage level of the at least one second type of clock signal is set to be higher than that of the at least one first type of clock signal, thereby allowing a DC bias applied to the TFT to be smaller as compared to the case where the at least one first type of clock signal is used.

In order to attain the above object, a method of the present invention is such that the TFT is an n-channel type transistor, and an active clock pulse duty-cycle of the at least one second type of clock signal is smaller than that of the at least one first type of clock signal.

According to the invention, it is possible to produce an effect that even if the at least one first type of clock signal and the at least one second type of clock signal are the same in high level voltage, a DC bias applied to the TFT can be set in accordance with the duty-cycle of the at least one second type of clock signal, i.e., can be made smaller, as compared to a case where the at least one first type of clock signal is used.

In order to attain the above object, a method of the present invention is such that the TFT is an n-channel type transistor, and an active clock pulse duty-cycle of the at least one second type of clock signal is larger than that of the at least one first type of clock signal.

According to the invention, it is possible to produce an effect that in a case where a threshold voltage of the TFT is not large, a voltage level is set to be an appropriate one (e.g., set to be small) while the duty-cycle of the at least one second type of clock signal is set to be larger than that of the at least one first type of clock signal, thereby allowing a DC bias applied to the TFT to be smaller as compared to the case where the at least one first type of clock signal is used.

In order to attain the above object, a method of the present invention is arranged such that the predetermined section is a pathway through which the output signal is transmitted.

According to the invention, it is possible to produce an effect that the pathway through which the output signal is transferred can stably sink down since the shift phenomenon of a threshold voltage can be suppressed.

In order to attain the above object, a method of the present invention is arranged such the shift register circuit is made of amorphous silicon.

According to the invention, it is possible to produce an effect that a floating spot specific to the shift register circuit which is made of amorphous silicon and which has only n-channel type TFTs can stably sink down since the shift phenomenon of a threshold voltage can be suppressed.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1 is a circuit diagram showing a configuration of each stage of a shift register of an embodiment of the present invention.

FIG. 2 is a circuit block diagram showing a configuration of a shift register circuit including stages each of which is configured as shown in FIG. 1.

FIG. 3 is a timing chart for explaining operations of each stage configured as shown in FIG. 1.

FIG. 4 is a timing chart of a modification of the operations of each stage configured as shown in FIG. 1.

FIG. 5 is a block diagram showing a configuration of a display device of the embodiment of the present invention.

FIG. 6 is a circuit block diagram showing a configuration of a first conventional shift register circuit.

FIG. 7 is a circuit diagram showing a configuration of each stage of the shift register circuit of FIG. 6.

FIG. 8 is a timing chart showing operations of each stage configured as shown in FIG. 7.

FIG. 9 is a circuit block diagram showing a configuration of a second conventional shift register circuit.

FIG. 10 is a circuit diagram showing a configuration of each stage of the shift register circuit of FIG. 9.

FIG. 11 is a timing chart showing operations of each stage configured as shown in FIG. 10.

FIG. 12 is a graph showing a relationship between a shift amount of a threshold voltage of a TFT and a stress time.

### REFERENCE SIGNS LIST

11: Liquid crystal display device (display device)
15a: Shift register circuit
SR: Stage
CK1, CK2: Clock signal (second type of clock signal)
CK3, CK4: Clock signal (first type of clock signal)
netA: Node (predetermined section, pathway through which an output signal is transmitted)
Gn: Output terminal (predetermined section, pathway through which an output signal is transmitted)
OUT: Output signal
Tr15, Tr16, Tr17: Transistor (TFT)

### DESCRIPTION OF EMBODIMENTS

An embodiment of the present invention is described below with reference to FIGS. 1 through 5.

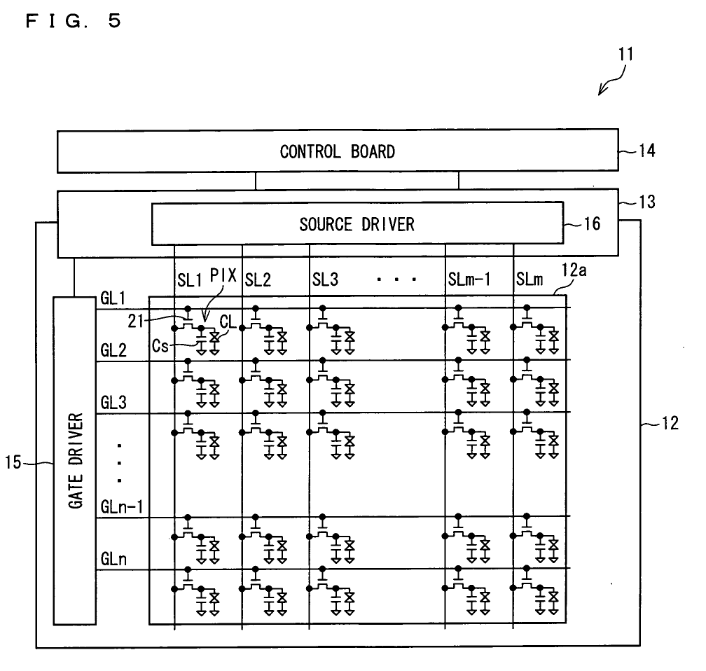

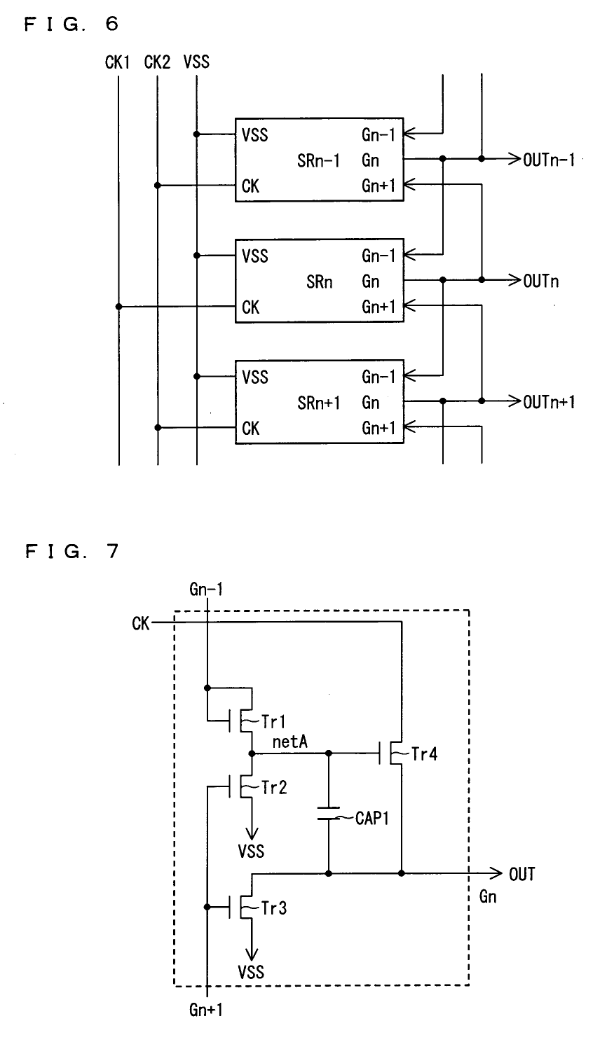

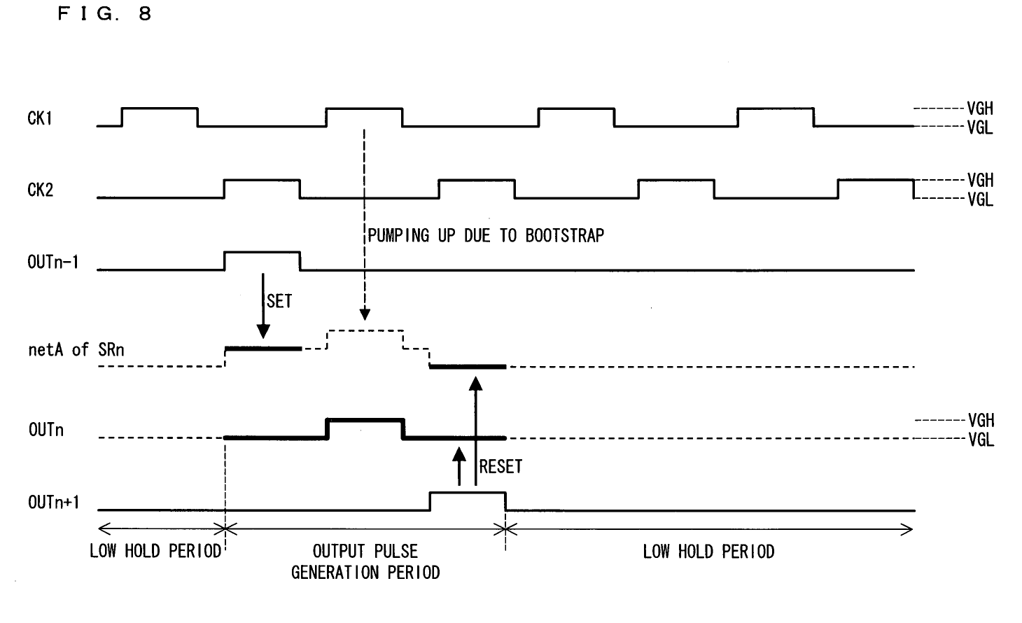

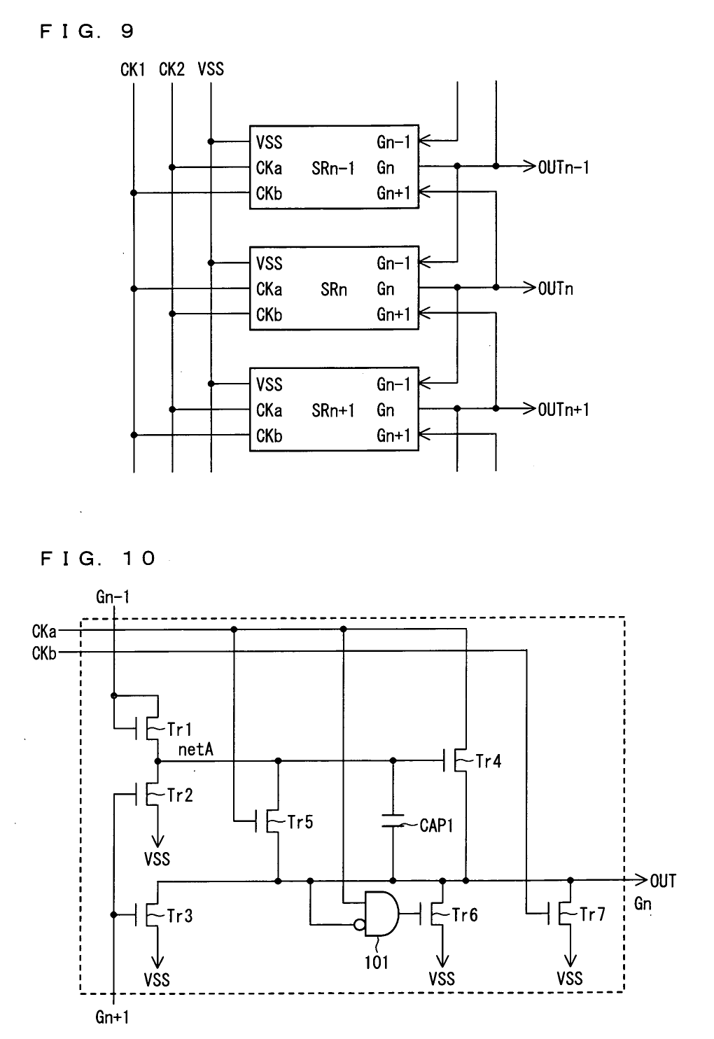

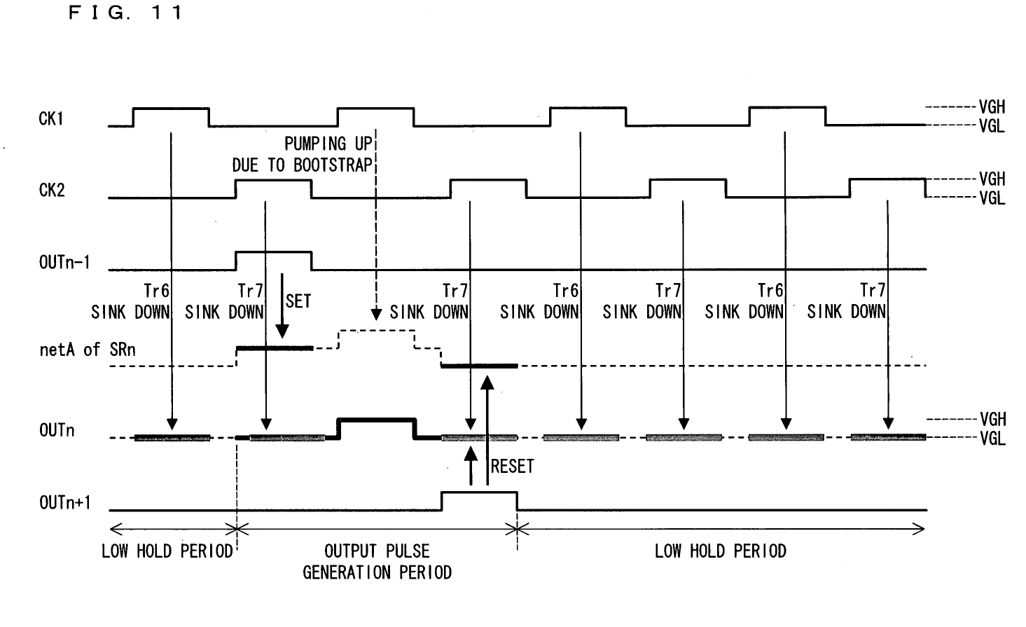

FIG. 5 shows a configuration of a liquid crystal display device 11 which is a display device of the present embodiment.

The liquid crystal display device 11 includes a display panel 12, a flexible printed circuit board 13, and a control board 14.

The display panel 12 is an active matrix display panel arranged such that, using amorphous silicon, polycrystalline silicon, CG silicon, microcrystalline silicon, or the like silicon, a display region 12a, a plurality of gate lines (scan signal lines) GL, a plurality of source lines (data signal lines) SL, and a gate driver (scan signal line driving circuit) 15 are built onto a glass substrate. The display region 12a is a region where a plurality of pixels PIX are arranged in a matrix manner. Each of the pixels PIX includes a TFT 21 that is a selection element of a pixel, a liquid crystal capacitor CL, and an auxiliary capacitor Cs. A gate of the TFT 21 is connected to the gate line GL, and a source of the TFT 21 is connected to the source line SL. The liquid crystal capacitor CL and auxiliary capacitor Cs are connected to a drain of the TFT 21.

The plurality of gate lines GL are gate lines GL1, GL2, GL3, . . . and GLn, which are connected to respective outputs of the gate driver (scan signal line driving circuit) 15. The plurality of source lines SL are source lines SL1, SL2, SL3, . . . SLm, which are connected to respective outputs of a source driver 16 that will be described later. Although not shown, an auxiliary capacitor line is formed to apply an auxiliary capacitor voltage to each of the auxiliary capacitors Cs of the pixels PIX.

The gate driver 15 is provided in a region adjoining one side of the display region 12a from which the gate lines GL extend over the display panel 12, and sequentially supplies a gate pulse (scanning pulse) to each of the gate lines GL. The gate driver 15 is provided in a region adjoining the other side of the display region 12a from which the gate lines GL extend over the display panel 12, and sequentially supplies a gate pulse (scanning pulse) to each of the gate lines GL. The gate driver 15 is built into the display panel 12, using amorphous silicon, polycrystalline silicon, CG silicon, microcrystalline silicon, or the like silicon, so as to be monolithically integrated with the display region 12a. Examples of the gate driver 15 can include all gate drivers referred to with the terms such as “monolithic gate driver”, “gate driver-free”, “built-in gate driver in panel”, and “gate in panel”.

The flexible printed circuit board 13 includes the source driver 16. The source driver 16 supplies a data signal to each of the source lines SL. The control board 14 is connected to the flexible printed circuit board 13 and supplies necessary signals and power to the gate driver 15 and the source driver 16. The control board 14 causes a level shifter circuit to generate, from a common clock signal, a clock signal which is outputted as a scan signal and a clock signal which drives a sink-down circuit in a shift register. This is described later. The signals and power to be supplied to the gate driver 15 from the control board 14 pass through the flexible printed circuit board 13, pass on the display panel 12, and are then supplied to the gate driver 15.

In a case where the gate driver 15 is monolithically integrated with the display panel 12 as above, the display panel 12 is suitably arranged such that pixels PIX included in a single row have the same color, thereby allowing the gate driver 15 to sequentially drive the RGB gate lines GL color by color. This eliminates the need for preparing source drivers 16 for the respective colors, thereby advantageously reducing the size of the source driver 16 or the flexible printed circuit board 13.

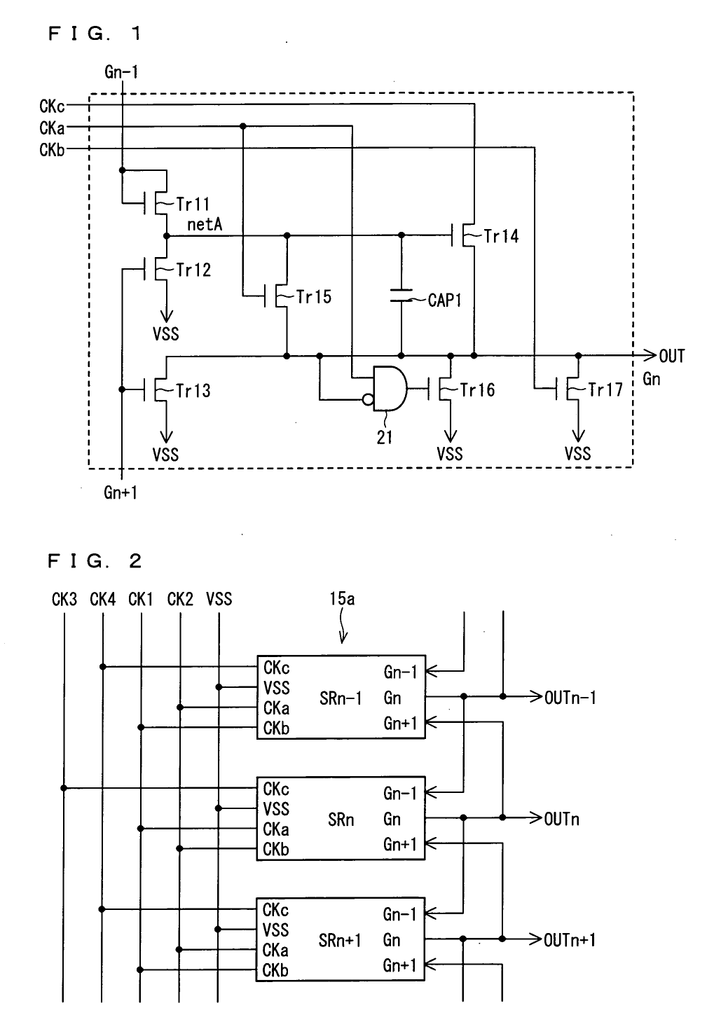

FIG. 2 shows an exemplary configuration of the gate driver 15.

As shown in FIG. 2, the gate driver 15 includes a shift register circuit 15a. The shift register circuit 15a includes stages SR ( . . . , SRn−1, SRn, SRn+1, . . . ) connected in cascade, each of which includes a set input terminal Gn−1, an output terminal Gn, a reset input terminal Gn+1, a Low power source input terminal VSS, and clock signal input terminals CKa, CKb, and CKc. To the set input terminal Gn−1 each stage SR, an output signal OUT ( . . . , OUTn−1, OUTn, OUTn+1, . . . ) of its preceding stage is inputted. To the set input terminal Gn−1 of a first stage SR1, a gate start pulse supplied from the control board 14 is inputted. An output terminal of each stage SR outputs an output signal OUT to a corresponding gate line GL. To the reset input terminal Gn+1 of each stage SR, an output signal OUT of its subsequent stage is inputted. To the Low power source input terminal VSS, a Low power source voltage VSS, which is a low-potential power source voltage in each stage SR, is inputted.

To a clock signal input terminal CKa, one of clock signals CK1 and CK2 (second type of clock signal) supplied from the control board 14 is inputted, and to a clock signal input terminal CKb, the other one of the clock signals CK1 and CK2 is inputted. Specifically, a first stage and a second stage are alternately provided, the first stage being such that the clock signal CK1 is inputted to the clock signal input terminal CKa and the clock signal CK2 is inputted to the clock signal input terminal CKb, and the second stage being such that the clock signal CK2 is inputted to the clock signal input terminal CKa and the clock signal CK1 is inputted to the clock signal input terminal CKb.

To a clock signal input terminal CKc of each of the stages SR, a clock signal CK3 or a clock signal CK4 (first type of clock signal) supplied from the control board 14 is inputted. To a clock signal input terminal CKc of the first stage, the clock signal CK3 is inputted, and to a clock signal input terminal CKc of the second stage, the clock signal CK4 is inputted.

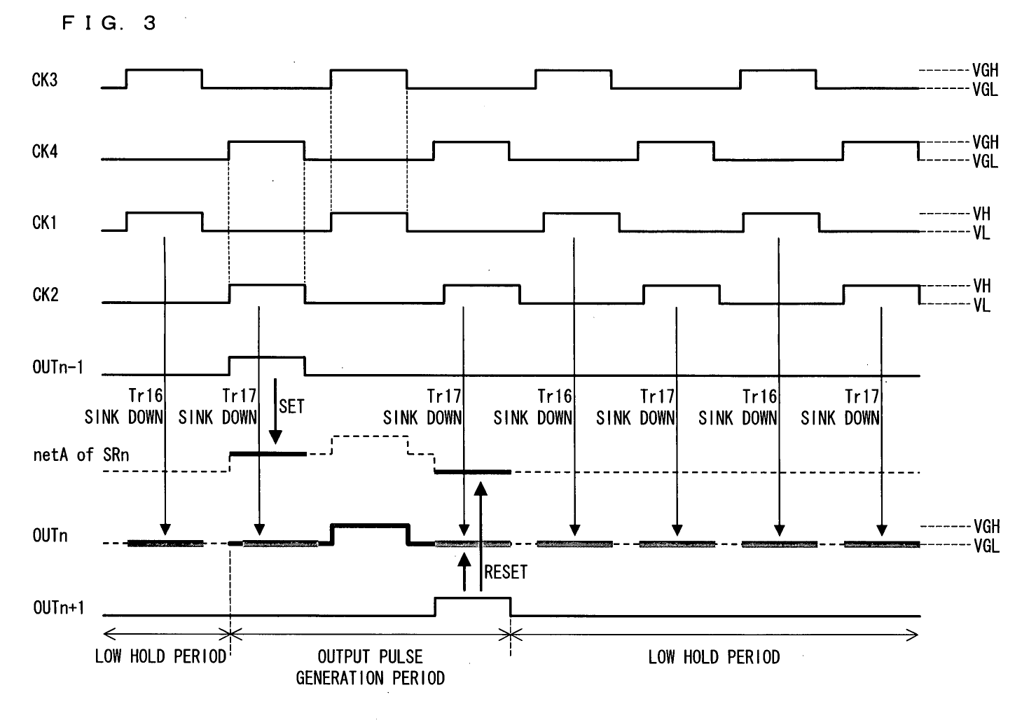

The clock signals CK1, CK2, CK3, and CK4 have waveforms as shown in FIG. 3, respectively. The clock signals CK1 and CK2 do not overlap with each other in an active clock pulse period. A high level voltage of each of the clock signals CK1 and CK2 is VH, and a low level voltage of each of the clock signals CK1 and CK2 is VL. The clock signal CK3 has the same timing as the clock signal CK1, and the clock signal CK4 has the same timing as the clock signal CK2. A high level voltage of each of the clock signals CK3 and CK4 is VGH, and a low level voltage of each of the clock signals CK3 and CK4 is VGL. As for the high level voltages, VGH>VH>0 is satisfied here. As for the low level voltages, VGL=VL is satisfied here, but it is also possible that VGL<VL.

The Low power source voltage VSS is equal to the low level voltage VGL of the clock signals CK3 and CK4. Further, in the present embodiment, the Low power source voltage VSS is equal to VL. Furthermore, in the present embodiment, a high level voltage of the AND gate 21 (later described) is set to VH, and a low level voltage of the AND gate 21 is set to VL.

The clock signals CK1 and CK2 are the ones which are translated, for example, from 0V/3V clock signals into −7V/16V clock signals in the control board 14 with the use of the level shifter circuit. The clock signals CK3 and CK4 are the ones which are translated, for example, from 0V/3V clock signals into −7V/22V clock signals in the control board 14 with the use of the level shifter circuit.

FIG. 1 shows an exemplary configuration of each of the stages SR of the shift register circuit 15a of FIG. 2.

Each of the stages SR includes transistors Tr11, Tr12, Tr13, Tr14, Tr15, Tr16 and Tr17, a capacitor CAP1, and the AND gate 21. These transistors are all n-channel type TFTs.

As to the transistor Tr11, a gate and a source are connected to a set input terminal Gn−1, and a source is connected to a gate of the transistor Tr14. As to the transistor Tr14, a drain is connected to a clock signal input terminal CKc, and a source is connected to an output terminal Gn. That is, the transistor Tr14 serves as a transfer gate to perform passage and interruption of a clock signal to be supplied to the clock input terminal CKc. The capacitor CAP1 is provided between the gate and the source of the transistor Tr14. A node that is conducted to the gate of the transistor Tr14 to have the same potential as it is referred to as a netA.

As to the transistor Tr12, a gate is connected to a reset input terminal Gn+1, a drain is connected to the node netA, and a source is connected to a Low power source input terminal VSS. As to the transistor Tr13, a gate is connected to the reset input terminal Gn+1, a drain is connected to the output terminal Gn, and a source is connected to the Low power source input terminal VSS.

As to the transistor Tr15, a gate is connected to a clock signal input terminal CKa, a drain is connected to the node netA, and a source is connected to the output terminal Gn. As to the transistor Tr16, a gate is connected to an output of the AND gate 21, a drain is connected to the output terminal Gn, and a source is connected to the Low power source input terminal VSS. As to the transistor Tr17, a gate is connected to a clock signal input terminal CKb, a drain is connected to the output terminal Gn, and a source is connected to the Low power source input terminal VSS. As to the AND gate 21, one input terminal is connected to the clock signal input terminal CKa, and the other low-active input terminal is connected to the output terminal Gn.

Each of the transistors Tr15, Tr16, and Tr17 is a sink-down transistor. The transistors Tr15, Tr16, and Tr17 and the AND gate 21 constitute a first circuit which connects, to a low-potential power source, a pathway (the node netA and the output terminal Gn) through which an output signal of each stage SR is transferred.

In the present embodiment, the first type of clock signals are used as clock signals outputted as scanning signals, and the second type of clock signals which are different from the first type of clock signals are used as clock signals supplied to gates of respective sink-down TFTs. In the present embodiment, the first type of clock signals are the two clock signals CK3 and CK4, and the second type of clock signals are the two clock signals CK1 and CK2. However, in general, the number of first type of clock signals and the number of second type of clock signals may be one or more, which number varies depending on how each stage SR is configured.

Next, with reference to FIG. 3, the following will describe operations of each stage SR configured as shown in FIG. 1.

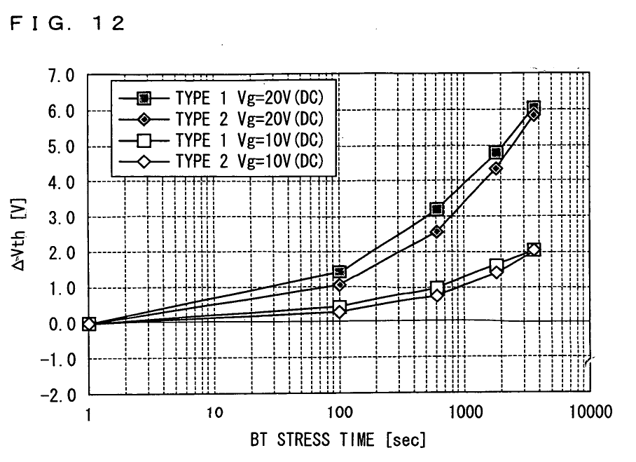

Until a shift pulse is supplied to the set input terminal Gn−1, the transistors Tr13 and Tr14 are in a high impedance state. This causes the output terminal Gn to be held Low. During the period in which the output terminal Gn is held Low, the transistor Tr15 is turned ON every time it receives a clock pulse of the clock signal CK1 or the clock signal CK2 (the clock signal CK1 in FIG. 3) inputted to the clock signal input terminal CKa, so that the node netA and the output terminal Gn are short-circuited. As long as the output terminal Gn is held Low, the AND gate 101 outputs a signal of high level every time it receives the clock pulse of the clock signal (the clock signal CK1 in FIG. 11) inputted to the clock signal input terminal CKa, so that the transistor Tr16 is turned ON. The transistor Tr17 is turned ON every time it receives a clock pulse of the clock signal CK1 or the clock signal CK2 (the clock signal CK2 in FIG. 3) inputted to the clock signal input terminal CKb, so that the output terminal Gn is connected to the Low power source voltage VSS.

A period in which the transistor Tr16 is being turned ON and a period in which the transistor Tr17 is being turned ON are alternated, and the output terminal Gn sinks down during these periods. The node netA sinks down while the transistor Tr15 is being turned ON since the transistor Tr16 is also being turned ON while the transistor Tr15 is being turned ON.

When to the set input terminal Gn−1 of each stage SR, a gate pulse (i.e., shift pulse) of an output signal OUT (OUTn−1 in FIG. 3) of its preceding stage is supplied, a period in which the output terminal Gn generates an output pulse starts. This causes the transistor Tr11 to be turned ON, which charges the capacitor CAP1. Charging of the capacitor CAP1 increases a potential of the node netA and causes the transistor Tr14 to be turned ON. This causes the clock signal (clock signal CK3 in FIG. 3) supplied through the clock signal input terminal CKc to appear at the source of the transistor Tr14. At the instant when the clock pulse is supplied to the clock signal input terminal CKc, the potential of the node netA is pumped up due to the bootstrap effect of the capacitor CAP1, and the incoming clock pulse is transmitted to the output terminal Gn of the stage SR and outputted from the output terminal Gn as a gate pulse (pulse of an output signal OUTn, here).

When the supply of the gate pulse to the set input terminal Gn−1 is completed, the transistor Tr11 is turned OFF. Then, in order to release charge retention caused by floating of the node netA and the output terminal Gn of the stage SR, the transistors Tr12 and Tr13 are turned ON by a reset pulse supplied to the reset input terminal Gn+1, and the node netA and the output terminal Gn are connected to the Low power source voltage VSS. This causes the transistor Tr14 to be turned OFF. When the supply of the reset pulse is completed, the period in which the output terminal Gn generates the output pulse ends, and the period in which the output terminal Gn is held Low starts again.

In this manner, gate pulses are sequentially outputted to respective gate lines.

According to the operation of FIG. 3, during the period in which the output terminal Gn is connected to the low level, a DC bias corresponding to an ON duty-cycle of approximately 50% is applied to the gates of the transistors Tr15, Tr16, and Tr17, and the high level voltage VH is set to be lower than the high level voltage VGH of the scanning signal. This allows a shift amount ΔVth of a threshold voltage of each of the sink-down TFTs to be kept very small.

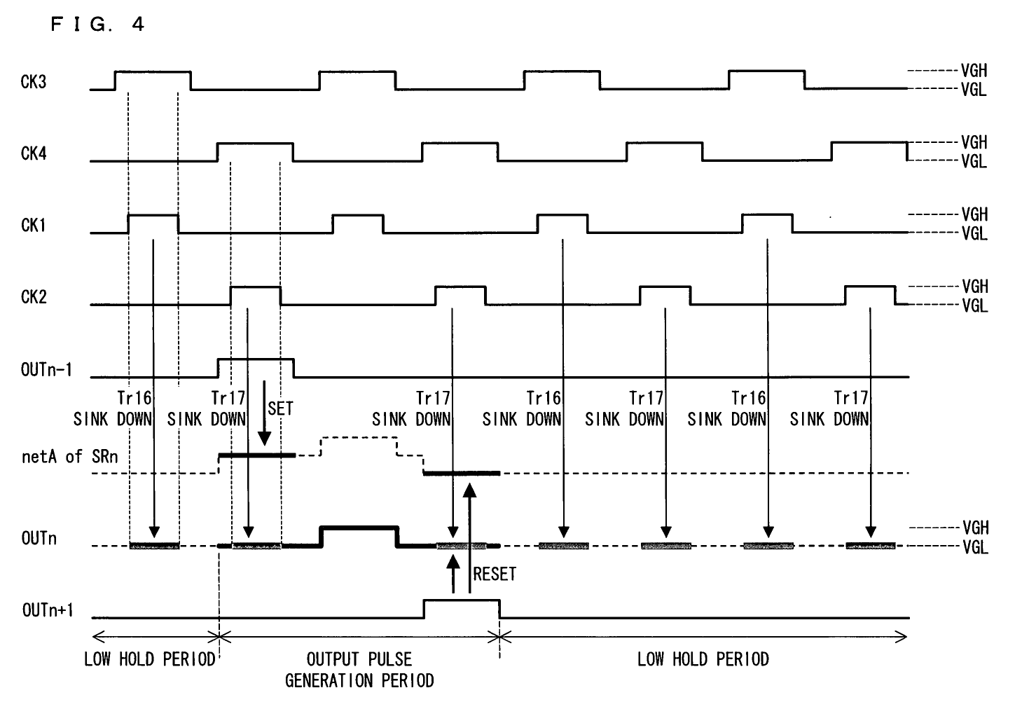

Next, with reference to FIG. 4, the following describes another method for driving the shift register 15a configured as shown in FIGS. 1 and 2.

In FIG. 4, it is assumed that a high level voltage of all of the clock signals CK1, CK2, CK3, and CK4 is VGH, and a low level voltage of all of the clock signals CK1, CK2, CK3, and CK4 is VGL. Further, an ON duty-cycle of the clock signals CK1 and CK2 is set to be smaller than that of the clock signals CK3 and CK4. Since the clock signals CK3 and CK4 are used as scanning signals, the ON duty-cycle of the clock signals CK3 and CK4 is identical to that of the case of FIG. 3.

In this case, a sink-down period of the transistors Tr15, Tr16, and Tr17 is shorter than the case of FIG. 3, as shown in FIG. 4. This allows a reduction in DC bias as in the case of FIG. 3, regardless of the fact that a large voltage (i.e., VGH) is used as the high level voltage of the clock signals CK1 and CK2.

This allows a shift amount ΔVth of a threshold voltage of each of the sink-down TFTs to be kept very small.

Note that it is also possible that the ON duty-cycle of the clock signals CK1 and CK2 is set to be smaller than that of the clock signals CK3 and CK4 as in FIG. 4 while the voltage levels of the clock signals CK1 through CK4 are set to be the same as those of FIG. 3.

The present embodiment has been described above. The present invention is also applicable to other display devices in which a shift register circuit is used, such as an EL display device.

The above description dealt with an example such as the one shown in FIG. 3 in which in a case where n-channel type TFTs are used, a high level voltage of the second type of clock signal is lower than that of the first type of clock signal. However, it is also possible that in a case where re-channel type TFTs are used, a high level voltage of the second type of clock signal is higher than that of the first type of clock signal.

For example, in a case where a threshold voltage of a TFT is large, the TFT is not sufficiently turned ON unless a large gate voltage is applied. However, the TFT can be sufficiently turned ON in a case where a duty-cycle is set to be an appropriate one (e.g., set to be small) while a voltage level of a second type of clock signal is set to be higher than that of a first type of clock signal. In this case, an active clock pulse duty-cycle of the second type of clock signal can be appropriately set in accordance with the number of sink-down TFTs and a sink-down period. It is therefore easy to make a DC bias applied to the TFT smaller as compared to a case where the first type of clock signal is used.

Further, the above description dealt with an example such as the one shown in FIG. 4 in which in a case where n-channel type TFTs are used, an active clock pulse duty-cycle of a second type of clock signal is smaller than that of a first type of clock signal. However, it is also possible that in a case where n-channel type TFTs are used, an active clock pulse duty-cycle of a second type of clock signal is larger than that of a first type of clock signal.

For example, in a case where a threshold voltage of a TFT is not large, the TFT is sufficiently turned ON even if a gate voltage to be applied is not so large. As such, the TFT can be sufficiently turned ON in a case where a voltage level is set to be an appropriate one (e.g., set to be small) while an active clock pulse duty-cycle of a second type of clock signal is set to be larger than that of a first type of clock signal. In this case, a voltage level of the second type of clock signal can be appropriately set in accordance with the threshold voltage. It is therefore easy to make a DC bias applied to the TFT smaller as compared to a case where the first type of clock signal is used.

The present invention is not limited to the description of the embodiments above, but may be altered by a skilled person within the scope of the claims. An embodiment based on a proper combination of technical means disclosed in different embodiments is encompassed in the technical scope of the present invention.

A shift register circuit of the present invention is a shift register circuit to which at least one first type of clock signal and at least one second type of clock signal are supplied, the shift register circuit including stages which are connected in cascade, the stages each including a first circuit which causes a predetermined section in a corresponding one of the stages to be connected to a low-potential power source, the first circuit being constituted by a TFT, the at least one first type of clock signal being used as a signal which is supplied to an output terminal of each of the stages so as to be outputted as an output signal, the at least one second type of clock signal being used as a signal which drives the first circuit.

The arrangement can produce an effect that it is possible to realize a shift register circuit that is capable of further suppressing a shift phenomenon of a threshold voltage of a TFT.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The present invention is suitably applicable especially to a display device such as a liquid crystal display device or an EL display device.

1. A shift register circuit to which at least one first type of clock signal and at least one second type of clock signal are supplied,
said shift register circuit comprising stages which are connected in cascade, the stages each including a first circuit which causes a predetermined section in a corresponding one of the stages to be connected to a low-potential power source, the first circuit being constituted by a TFT,
said at least one first type of clock signal being used as a signal which is transferred to an output terminal of each of the stages so as to be outputted as an output signal,
said at least one second type of clock signal being used as a signal which drives the first circuit.

2. The shift register circuit according to claim 1, wherein:
the TFT is an n-channel type transistor, and
a high level voltage of said at least one second type of clock signal is lower than that of said at least one first type of clock signal.

3. The shift register circuit according to claim 1, wherein:
the TFT is an n-channel type transistor, and
a high level voltage of said at least one second type of clock signal is higher than that of said at least one first type of clock signal.

4. The shift register circuit according to claim 1, wherein:
the TFT is an n-channel type transistor, and
an active clock pulse duty-cycle of said at least one second type of clock signal is smaller than that of said at least one first type of clock signal.

5. The shift register circuit according to claim 1, wherein:
the TFT is an n-channel type transistor, and
an active clock pulse duty-cycle of said at least one second type of clock signal is larger than that of said at least one first type of clock signal.

6. The shift register circuit according to claim 1, wherein:
the predetermined section is a pathway through which the output signal is transmitted.

7. The shift register circuit according to claim 1, wherein:
the shift register circuit is formed from amorphous silicon.

8. The shift register circuit according to claim 1, wherein:
the shift register circuit is formed from polycrystalline silicon.

9. The shift register circuit according to claim 1, wherein:
the shift register circuit is formed from CG silicon.

10. The shift register circuit according to claim 1, wherein:
the shift register circuit is formed from microcrystalline silicon.

11. A display device comprising a shift register circuit set forth in claim 1, the shift register circuit being used for display driving.

12. The display device according to claim 11, wherein:
the shift register circuit is used as a scan signal line driving circuit.

13. The display device according to claim 11, wherein:
the shift register circuit is formed on a display panel so as to be monolithically integrated with a display region.

14. A method for driving a shift register circuit which includes stages connected in cascade, the stages each including a first circuit which causes a predetermined section in a corresponding one of the stages to be connected to a low-potential power source, the first circuit being constituted by a TFT,
said method comprising the step of:
supplying at least one first type of clock signal and at least one second type of clock signal to the shift register circuit,
said at least one first type of clock signal being used as a signal which is transferred to an output terminal of each of the stages so as to be outputted as an output signal,
said at least one second type of clock signal being used as a signal which drives the first circuit.

15. The method according to claim 14, wherein:
the TFT is an n-channel type transistor, and
a high level voltage of said at least one second type of clock signal is lower than that of said at least one first type of clock signal.

16. The method according to claim 14, wherein:
the TFT is an n-channel type transistor, and
a high level voltage of said at least one second type of clock signal is higher than that of said at least one first type of clock signal.

17. The method according to claim 14, wherein:
the TFT an n-channel type transistor, and
an active clock pulse duty-cycle of said at least one second type of clock signal is smaller than that of said at least one first type of clock signal.

18. The method according to claim 14, wherein:
the TFT is an n-channel type transistor, and
an active clock pulse duty-cycle of said at least one second type of clock signal is larger than that of said at least one first type of clock signal.

19. The method according to claim 14, wherein:
the predetermined section is a pathway through which the output signal is transmitted.

20. The method according to claim 14, wherein:
the shift register circuit is formed from amorphous silicon.
